(19) United States
(12) Patent Application Publication
(10) Pub. No.: US 2025/0125002 A1
(43) Pub. Date: Apr. 17, 2025

(54) ELECTRONIC SYSTEM RELATED TO DETECTING A RESULT OF A RUPTURE OPERATION

(71) Applicant: SK hynix Inc., Icheon-si Gyeonggi-do (KR)

(72) Inventors: Dong Beom LEE, Icheon-si Gyeonggi-do (KR); Hyeong Soo JEONG, Icheon-si Gyeonggi-do (KR)

(73) Assignee: SK hynix Inc., Icheon-si Gyeonggi-do (KR)

(21) Appl. No.: 18/411,412

(22) Filed: Jan. 12, 2024

(30) Foreign Application Priority Data
Oct. 17, 2023 (KR) 10-2023-0139064

(51) Int. Cl. G11C 29/00; G11C 29/18; G11C 29/52

(52) U.S. Cl. CPC G11C 29/787; G11C 29/18; G11C 29/52

(57) ABSTRACT

An electronic device includes a first counting circuit configured to generate a first counting signal based on a comparison signal that is generated by comparing a first row address after the start of a first bootup operation and first fuse data that are generated by a first rupture operation, a second counting circuit configured to generate a second counting signal based on the comparison signal that is generated by comparing a second row address after the start of a second bootup operation and second fuse data that are generated by a second rupture operation, and a repair comparison circuit configured to generate a repair detection signal for detecting whether the first and second rupture operations are additionally performed by comparing the first counting signal with the second counting signal and configured to output the repair detection signal.

### CROSS-REFERENCE TO RELATED APPLICATION

The present application claims priority under 35 U.S.C. § 119(a) to Korean Patent Application No. 10-2023-0139064, filed in the Korean Intellectual Property Office on Oct. 17, 2023, the entire disclosure of which is incorporated herein by reference.

### BACKGROUND

### 1. Technical Field

The present disclosure generally relates to an electronic system, and more particularly, to an electronic system related to comparing a row address for selecting a memory cell having an error occurred after the start of a bootup operation and fuse data that are generated by a rupture operation and detecting the results of the rupture operation based on a result of the comparison.

### 2. Related Art

As semiconductor devices are highly integrated and have an increased storage capacity, the possibility that a fail occurs in a memory cell in a process of producing memory cells is increased, which acts as a factor to degrade a production yield of the memory cells. In general, if a semiconductor device has several defective memory cells, even only one defective cell, the semiconductor device cannot be released as a product.

In order to improve a reduction of the yield according to the higher integration of semiconductor devices as described above, several attempts are made. A representative one of the attempts is to use a repair using a fuse.

In the semiconductor device, in general, a repair technology that is used so that a chip can operate normally by repairing a cell having a fail occurred into a normal cell includes two methods. A first method is a fuse cutting method using a laser device. A second method is a method of inducing the rupture of the material of a fuse so that the state of the fuse becomes electrically short-circuited by applying a predetermined amount of a high current to the material of the fuse. In particular, the second method is a method which may be used after the package assembly of a chip is completed, and is called an anti-fuse method. A manufacturer who manufactures chips prefers the anti-fuse method to the fuse cutting method using a laser in that a fail cell that occurs in its package state can be repaired into a normal cell.

### SUMMARY

In an embodiment, an electronic device may include a first counting circuit configured to generate a first counting signal based on a comparison signal that is generated by comparing a first row address after the start of a first bootup operation and first fuse data that are generated by a first rupture operation, a second counting circuit configured to generate a second counting signal based on the comparison signal that is generated by comparing a second row address after the start of a second bootup operation and second fuse data that are generated by a second rupture operation, and a repair comparison circuit configured to generate a repair detection signal for detecting whether the first and second rupture operations are additionally performed by comparing the first counting signal with the second counting signal and configured to output the repair detection signal.

In an embodiment, an electronic device may include a repair control circuit configured to generate a bootup counting signal including a pulse that is periodically generated after the start of first and second bootup operations, configured to generate a comparison signal by comparing first and second row addresses that are input after the start of the first and second bootup operations and first and second fuse data, configured to generate a repair result signal for detecting whether the first and second rupture operations are additionally performed based on the comparison signal, and configured to output the repair result signal to the outside of the electronic device when a repair output signal is input, and a fuse circuit configured to output the first and second fuse data that are generated by the first and second rupture operations based on the bootup counting signal.

In an embodiment, an electronic device may include a repair control circuit configured to generate a bootup counting signal including a pulse that is periodically generated after the start of first and second bootup operations, configured to generate a comparison signal by comparing first and second row addresses that are input after the start of the first and second bootup operations and first and second fuse data, configured to generate a repair result signal for detecting whether first and second rupture operations are additionally performed based on the comparison signal and first and second fuse addresses, and configured to output the repair result signal to the outside of the electronic device when the repair output signal is input, and a fuse circuit configured to output first and second fuse data that are generated by the first and second rupture operations and the first and second fuse addresses based on the bootup counting signal.

### BRIEF DESCRIPTION OF THE DRAWINGS

FIG. 1 is a block diagram illustrating a construction of an electronic system according to an embodiment of the present disclosure.

FIG. 2 is a block diagram illustrating a construction according to an embodiment of an electronic device that is included in the electronic system illustrated in FIG. 1.

FIG. 3 is a block diagram illustrating a construction according to an embodiment of a memory circuit that is included in the electronic device illustrated in FIG. 2.

FIG. 4 is a block diagram illustrating a construction according to an embodiment of a fuse circuit that is included in the electronic device illustrated in FIG. 2.

FIG. 5 is a block diagram illustrating a construction according to an embodiment of a repair control circuit that is included in the electronic device illustrated in FIG. 2.

FIG. 6 is a block diagram illustrating a construction according to an embodiment of a bootup control circuit that is included in the repair control circuit illustrated in FIG. 5.

FIG. 7 is a block diagram illustrating a construction according to an embodiment of a repair detection circuit that is included in the repair control circuit illustrated in FIG. 5.

FIG. 8 is a block diagram illustrating a construction according to an embodiment of a repair detection signal generation circuit that is included in the repair detection circuit illustrated in FIG. 7.

FIG. 9 is a timing diagram for describing a first bootup operation of the electronic system according to an embodiment of the present disclosure.

FIG. 10 is a timing diagram for describing a second bootup operation of the electronic system according to an embodiment of the present disclosure.

FIG. 11 is a block diagram illustrating a construction according to another embodiment of an electronic device that is included in the electronic system illustrated in FIG. 1.

FIG. 12 is a block diagram illustrating a construction according to an embodiment of a repair control circuit that is included in the electronic device illustrated in FIG. 11.

FIG. 13 is a block diagram illustrating a construction according to an embodiment of a repair detection circuit that is included in the repair control circuit illustrated in FIG. 12.

FIG. 14 is a block diagram illustrating a construction according to an embodiment of a repair detection signal generation circuit that is included in the repair detection circuit illustrated in FIG. 13.

FIG. 15 is a diagram illustrating a construction according to an embodiment of an electronic system to which the electronic system illustrated in FIGS. 1 and 14 has been applied.

### DETAILED DESCRIPTION

In the descriptions of the following embodiments, the term “preset” indicates that the numerical value of a parameter is previously decided, when the parameter is used in a process or algorithm. According to an embodiment, the numerical value of the parameter may be set when the process or algorithm is started or while the process or algorithm is performed.

Terms such as “first” and “second,” which are used to distinguish among various components, are not limited by the components. For example, a first component may be referred to as a second component, and vice versa.

When one component is referred to as being “coupled” or “connected” to another component, it should be understood that the components may be directly coupled or connected to each other or coupled or connected to each other through another component interposed therebetween. In contrast, when one component is referred to as being “directly coupled” or “directly connected” to another component, it should be understood that the components are directly coupled or connected to each other without another component interposed therebetween.

A “logic high level” and a “logic low level” are used to describe the logic levels of signals. A signal having a “logic high level” is distinguished from a signal having a “logic low level.” For example, when a signal having a first voltage corresponds to a signal having a “logic high level,” a signal having a second voltage may correspond to a signal having a “logic low level.” According to an embodiment, a “logic high level” may be set to a voltage higher than a “logic low level.” According to an embodiment, the logic levels of signals may be set to different logic levels or opposite logic levels. For example, a signal having a logic high level may be set to have a logic low level in some embodiments, and a signal having a logic low level may be set to have a logic high level in some embodiments.

Hereafter, the present disclosure will be described in more detail through embodiments. The embodiments are only used to exemplify the present disclosure, and the scope of the present disclosure is not limited by the embodiments.

Various embodiments of the present disclosure provide an electronic system for comparing a row address for selecting a memory cell having an error occurred after the start of a bootup operation and fuse data that are generated by a rupture operation and detecting whether a rupture operation is additionally performed based on a result of the comparison.

According to an embodiment of the present disclosure, it is possible to compare a row address for selecting a memory cell having an error occurred after the start of a bootup operation and fuse data that are generated by a rupture operation and to detect the results of the rupture operation based on a result of the comparison.

Furthermore, according to an embodiment of the present disclosure, it is possible to detect whether a rupture operation is additionally performed between bootup operations that are consecutively performed, by comparing a row address for selecting a memory cell having an error occurred after the start of a bootup operation and fuse data that are generated by a rupture operation and detecting a result of the comparison.

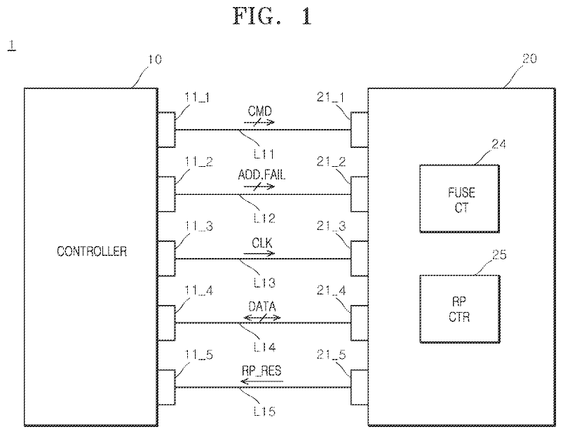

As illustrated in FIG. 1, an electronic system 1 according to an embodiment of the present disclosure may include a controller 10 and an electronic device 20. The electronic device 20 may include a fuse circuit (RUP CTR) 24 and a repair control circuit (RP CTR) 25.

The controller 10 may include a first control pin 11_1, a second control pin 11_2, a third control pin 11_3, a fourth control pin 11_4, and a fifth control pin 11_5. The electronic device 20 may include a first device pin 21_1, a second device pin 21_2, a third device pin 21_3, a fourth device pin 21_4, and a fifth device pin 21_5. A first transmission line L11 may be connected between the first control pin 11_1 and the first device pin 21_1. A second transmission line L12 may be connected between the second control pin 11_2 and the second device pin 21_2. A third transmission line L13 may be connected between the third control pin 11_3 and the third device pin 21_3. A fourth transmission line L14 may be connected between the fourth control pin 11_4 and the fourth device pin 21_4. A fifth transmission line L15 may be connected between the fifth control pin 11_5 and the fifth device pin 21_5.

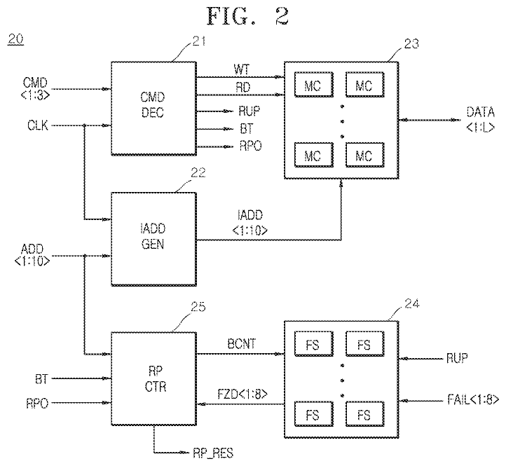

The controller 10 may transmit a command CMD for controlling the electronic device 20 to the electronic device 20 through the first transmission line L11. The controller 10 may transmit an address ADD for controlling the electronic device 20 to the electronic device 20 through the second transmission line L12. The controller 10 may transmit a fail address FAIL, that is, a location at which a fail has occurred, to the electronic device 20 through the second transmission line L12. The controller 10 may transmit a clock CLK to the electronic device 20 through the third transmission line L13. The controller 10 may transmit data DATA to the electronic device 20 through the fourth transmission line L14. The controller 10 may receive data DATA from the electronic device 20 through the fourth transmission line L14. The electronic device 20 may transmit a repair result signal RP_RES to the controller 10 through the fifth transmission line L15. The command CMD may include a plurality of bits, and may be set as a signal for controlling an operation of the electronic device 20. The address ADD may include a plurality of bits, and may be set as a signal for selecting a plurality of memory cells that are included in a memory circuit (23 in FIG. 2). The clock CLK may be set as a signal that is periodically toggled in order to synchronize operations of the controller 10 and the electronic device 20. The repair result signal RP_RES may be set as a signal for detecting whether a rupture operation is additionally performed.

The controller 10 may output the command CMD and the address ADD for performing a write operation, a read operation, a rupture operation, a bootup operation, and a rupture detection operation. The controller 10 may output the fail address FAIL, that is, a location at which a fail has occurred, after the start of a rupture operation. The controller 10 may output the data DATA after the start of a write operation. The controller 10 may receive the data DATA after the start of a read operation. The controller 10 may detect the results of a rupture operation by receiving the repair result signal RP_RES after the start of a rupture detection operation. The controller 10 may detect that a rupture operation is additionally performed when the repair result signal RP_RES is enabled after the start of a rupture detection operation. The controller 10 may detect that a rupture operation is not additionally performed when the repair result signal RP_RES is disabled after the start of a rupture detection operation.

The fuse circuit 24 may include a plurality of fuses (FS in FIG. 2). The fuse circuit 24 may rupture the plurality of fuses (FS in FIG. 2) in order to generate a fail address FAIL<1:8> and fuse data (FZD<1:8> in FIG. 2) having a plurality of identical combinations after the start of a rupture operation. The fuse circuit 24 may output the fuse data (FZD<1:8> in FIG. 2) that are generated by a rupture operation, based on a bootup counting signal (BCNT in FIG. 2) that includes a pulse that is periodically generated after the start of a bootup operation.

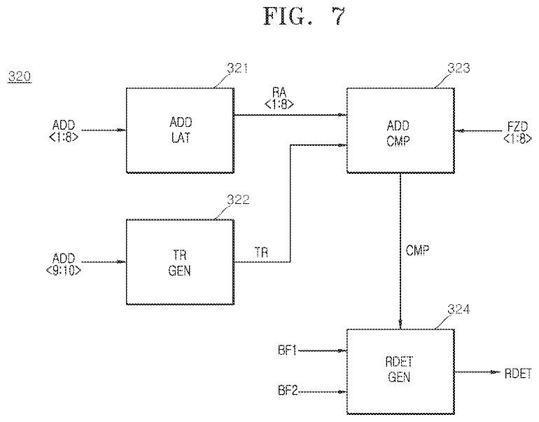

The repair control circuit 25 may generate the bootup counting signal (BCNT in FIG. 2) that includes a pulse that is periodically generated after the start of a bootup operation. The repair control circuit 25 may generate a comparison signal (CMP in FIG. 7) by comparing the address ADD that is input after the start of a bootup operation and the fuse data (FZD<1:8> in FIG. 2). The repair control circuit 25 may generate the repair result signal RP_RES based on the comparison signal (CMP in FIG. 7). The repair control circuit 25 may output the repair result signal RP_RES to the controller 10 after the start of a rupture operation detection operation.

The electronic device 20 may store the data DATA in the memory cell (MC in FIG. 2) that is selected based on the command CMD and the address ADD after the start of a write operation. The electronic device 20 may output the data DATA that has been stored in the memory cell (MC in FIG. 2) that is selected based on the command CMD and the address ADD after the start of a read operation. The electronic device 20 may rupture the plurality of fuses (FS in FIG. 2) in order to generate the fuse data (FZD<1:8> in FIG. 2) having the same combination as the fail address FAIL<1:8> for selecting a memory cell having a fail occurring after the start of a rupture operation. The electronic device 20 may sequentially output the fuse data (FZD<1:8> in FIG. 2) that have been stored in the fuse (FS in FIG. 2), by a rupture operation RUPTURE after the start of a bootup operation. The electronic device 20 may generate the comparison signal (CMP in FIG. 7) by comparing the address ADD that is input after the start of a bootup operation and the fuse data (FZD<1:8> in FIG. 2), and may generate the repair result signal RP_RES based on the comparison signal (CMP in FIG. 7). The electronic device 20 may output the repair result signal RP_RES to the controller 10 after the start of a rupture detection operation.

FIG. 2 is a block diagram illustrating a construction according to an embodiment of the electronic device 20 that is included in the electronic system 1. The electronic device 20 may include a command decoder (CMD DEC) 21, an internal address generation circuit (IADD GEN) 22, the memory circuit 23, the fuse circuit 24, and a repair control circuit (RP CTR) 25.

The command decoder 21 may generate a write signal WT, a read signal RD, a rupture signal RUP, a bootup signal BT, and a repair output signal RPO by decoding a command CMD<1:3> in synchronization with a clock CLK. The command decoder 21 may generate the write signal WT that is enabled when the command CMD<1:3> that is input in synchronization with the clock CLK has a logic level combination for performing a write operation. The command decoder 21 may generate the read signal RD that is enabled when the command CMD<1:3> that is input in synchronization with the clock CLK has a logic level combination for performing a read operation. The command decoder 21 may generate the rupture signal RUP that is enabled when the command CMD<1:3> that is input in synchronization with the clock CLK has a logic level combination for performing a rupture operation. The command decoder 21 may generate the bootup signal BT that is enabled when the command CMD<1:3> that is input in synchronization with the clock CLK has a logic level combination for performing first and second bootup operations. The command decoder 21 may generate the repair output signal RPO that is enabled when the command CMD<1:3> that is input in synchronization with the clock CLK has a logic level combination for performing a rupture detection operation. The number of bits of the command CMD<1:3> has been set to “3”, but may be set as various numbers of bits in order to generate various signals.

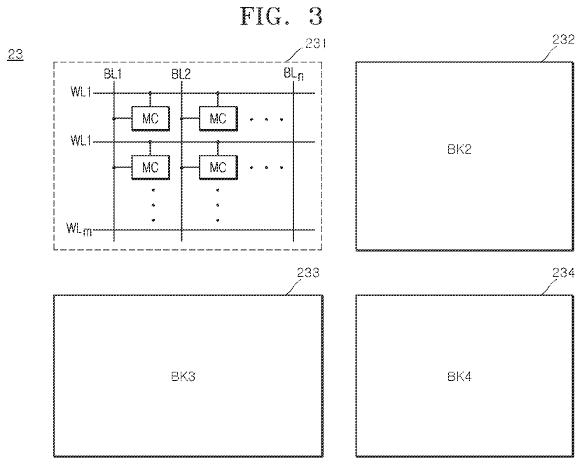

The internal address generation circuit 22 may generate an internal address IADD<1:10> by buffering the address ADD<1:10> in synchronization with the clock CLK. First to eighth bits IADD<1:8> of the internal address may be set as bits for selecting a plurality of memory cells that are included in the memory circuit 23. Ninth and tenth bits IADD<9:10> of the internal address may be set as bits for selecting the first to fourth banks (231 to 234 in FIG. 3) that are included in the memory circuit 23. The number of bits of each of the address ADD<1:10> and the internal address IADD<1:10> has been set to “10”, but may be set as various numbers of bits in order to select various numbers of memory cells MC.

The memory circuit 23 may include the plurality of memory cells MC. The memory circuit 23 may store data DATA<1:L> in the memory cell MC that is selected based on the internal address IADD<1:10> when the write signal WT is generated. The memory circuit 23 may output the data DATA<1:L> that have been stored in the memory cell MC that is selected based on the internal address IADD<1:10> when the read signal RD is generated. The number of bits of the data DATA<1:L> may be set as “L”. “L” may be set as a positive integer. According to an embodiment, the number of bits of the data may be variously set like “8”, “16”, or “32” etc. A case in which the number of bits of the data is “8” may mean a case in which the number of bits of the data that are input and output after the start of one write and read operation is 8.

The fuse circuit 24 may include the plurality of fuses FS. The fuse circuit 24 may rupture the plurality of fuses FS in order to generate the fuse data FZD<1:8> having the same combination as the fail address FAIL<1:8> for selecting a memory cell having a fail that has occurred, among the plurality of memory cells MC, when the rupture signal RUP is enabled. The fuse circuit 24 may output the first and second fuse data FZD<1:8> that are generated by first and second rupture operations, based on the bootup counting signal BCNT that includes a pulse that is periodically generated after the start of first and second bootup operations. The number of bits of the fuse data FZD<1:8> may be set to “8”. The number of bits of the fuse data FZD<1:8> and the number of bits of an address ADD<1:8> for selecting a plurality of memory cells that are included in the memory circuit 23 may be identically set. If the plurality of fuses FS has already been ruptured by the fail address FAIL<1:8> after the start of the first bootup operation, the fuse circuit 24 may generate the first fuse data (FZD<1:8> in FIG. 2) by rupturing a plurality of new fuses FS without using a plurality of fuses FS that have already been ruptured. The fuse circuit 24 may output the second fuse data (FZD<1:8> in FIG. 2) that are generated by rupturing the plurality of new fuses FS after the start of the second bootup operation. The first fuse data FZD<1:8> may mean fuse data that are output after the start of the first bootup operation. The second fuse data FZD<1:8> may mean fuse data that are output after the start of the second bootup operation. The first and second rupture operations may each be set as an operation of electrically cutting the plurality of fuses FS in order to generate the fuse data FZD<1:8> having the same logic level combination as the internal address IADD<1:8> for selecting the memory cell MC having a fail that has occurred.

The repair control circuit 25 may generate the bootup counting signal BCNT that includes a pulse that is periodically generated after the start of first and second bootup operations. The repair control circuit 25 may generate the comparison signal (CMP in FIG. 7) by comparing the address ADD<1:8> that is input after the start of the first and second bootup operations and the fuse data FZD<1:8>. The repair control circuit 25 may generate the repair result signal RP_RES based on the comparison signal (CMP in FIG. 7). The repair control circuit 25 may output the repair result signal RP_RES to the controller 10 when the repair output signal RPO is enabled after the start of a rupture detection operation.

The electronic device 20 may store the data DATA<1:L> in the memory cell MC that is selected based on the command CMD<1:3> and the address ADD<1:10> after the start of a write operation. The electronic device 20 may output the data DATA<1:L> that have been stored in the memory cell MC that is selected based on the command CMD<1:3> and the address ADD<1:10> after the start of a read operation. The electronic device 20 may rupture the plurality of fuses FS in order to generate the fuse data FZD<1:8> having the same combination as the fail address FAIL<1:8> for selecting a memory cell having a fail occurring after the start of a rupture operation. The electronic device 20 may sequentially output the fuse data FZD<1:8> that have been stored in the plurality of fuses FS by a rupture operation RUPTURE after the start of a bootup operation. The electronic device 20 may generate the comparison signal (CMP in FIG. 7) by comparing the address ADD<1:10> that is input after the start of a bootup operation and the fuse data FZD<1:8>, and may generate the repair result signal RP_RES based on the comparison signal (CMP in FIG. 7). The electronic device 20 may output the repair result signal RP_RES to the controller 10 after the start of a rupture detection operation.

FIG. 3 is a block diagram illustrating a construction according to an embodiment of the memory circuit 23 that is included in the electronic device 20. The memory circuit 23 may include a first bank 231, a second bank (BK2) 232, a third bank (BK3) 233, and a fourth bank (BK4) 234.

The first bank 231 may include first to m-th word lines WL1 to WLm and first to n-th bit lines BL1 to BLn. The first bank 231 may include the plurality of memory cells MC at which the first to m-th word lines WL1 to WLm and the first to n-th bit lines BL1 to BLn are intersected and that are connected to the first to m-th word lines WL1 to WLm and the first to n-th bit lines BL1 to BLn.

The first bank 231 may be activated when all of the ninth and tenth bits IADD<9:10> of the internal address have a logic low level. One of the first to m-th word lines WL1 to WLm and one of the first to n-th bit lines BL1 to BLn may be activated by the first to eighth bits IADD<1:8> of the internal address. The first bank may store the data DATA<1:L> in the memory cell MC that is connected to one of the first to m-th word lines WL1 to WLm and one of the first to n-th bit lines BL1 to BLn, which are activated after the start of a write operation. The first bank may output the data DATA<1:L> that have been stored in the memory cell MC that is connected to one of the first to m-th word lines WL1 to WLm and one of the first to n-th bit lines BL1 to BLn, which are activated after the start of a read operation.

The second bank 232, the third bank 233, and the fourth bank 234 may be selectively activated based on a logic level combination of the ninth and tenth bits IADD<9:10> of the internal address, and may each be implemented to have the same construction as the first bank 231 and may each perform the same operation as the first bank 231 and thus a detailed description thereof is omitted.

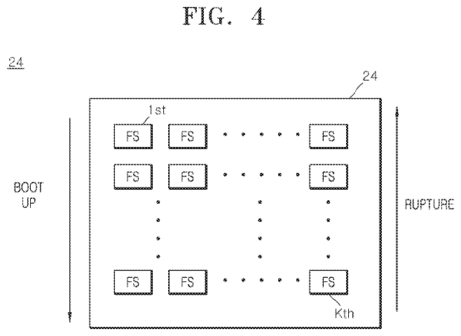

FIG. 4 is a block diagram illustrating a construction according to an embodiment of the fuse circuit 24 that is included in the electronic device 20. The fuse circuit 24 may include the plurality of fuses FS.

The fuse circuit 24 may rupture the plurality of fuses FS in order to generate first and second fuse data (FZD<1:8> in FIG. 2) having the same combination as the fail address FAIL<1:8> for selecting a memory cell having a fail that has occurred, among the plurality of memory cells (MC in FIG. 2), when the rupture signal RUP is enabled. The fuse circuit 24 may output the first fuse data (FZD<1:8> in FIG. 2) that are generated by a first rupture operation, based on the bootup counting signal (BCNT in FIG. 2) that includes a pulse that is periodically generated after the start of a first bootup operation. The fuse circuit 24 may output the second fuse data (FZD<1:8> in FIG. 2) that is generated by a second rupture operation, based on the bootup counting signal (BCNT in FIG. 2) that includes a pulse that is periodically generated after the start of a second bootup operation. If the plurality of fuses FS has already been ruptured by the fail address FAIL<1:8> after the start of the first bootup operation, the fuse circuit 24 may generate the first fuse data (FZD<1:8> in FIG. 2) by rupturing a plurality of new fuses FS without using a plurality of fuses FS that have already been ruptured. The fuse circuit 24 may output the second fuse data (FZD<1:8> in FIG. 2) that are generated by rupturing the plurality of new fuses FS after the start of the second bootup operation.

An operation of the fuse circuit 24 performing first and second rupture operations and first and second bootup operations may be described as follows with reference to FIG. 4.

The fuse circuit 24 may be ruptured so that the fuse data (FZD<1:8> in FIG. 2) having the same combination as the fail address FAIL<1:8> are generated from the last fuse K-th FS after the start of first and second rupture operations RUPTURE. The fuse circuit 24 may generate the fuse data (FZD<1:8> in FIG. 2) as the plurality of fuses FS is ruptured from the last fuse K-th FS to the first fuse 1^{st} FS in reverse order after the start of the first and second rupture operations RUPTURE.

The fuse circuit 24 may output, as the first fuse data (FZD<1:8> in FIG. 2), fuse data that are generated after the start of a rupture operation RUPTURE from the first fuse 1^{st} FS after the start of a first bootup operation BOOT UP. The fuse circuit 24 may output, as the first fuse data (FZD<1:8> in FIG. 2), fuse data that are sequentially generated after the start of a rupture operation RUPTURE from the first fuse 1^{st} FS to the last fuse K-th FS after the start of the first bootup operation BOOT UP.

The fuse circuit 24 may output, as the second fuse data (FZD<1:8> in FIG. 2), fuse data that are generated after the start of a second rupture operation RUPTURE from the first fuse 1^{st} FS after the start of a second bootup operation BOOT UP. The fuse circuit 24 may output, as the second fuse data (FZD<1:8> in FIG. 2), fuse data that are sequentially generated after the start of a rupture operation RUPTURE from the first fuse 1^{st} FS to the last fuse K-th FS after the start of the second bootup operation BOOT UP.

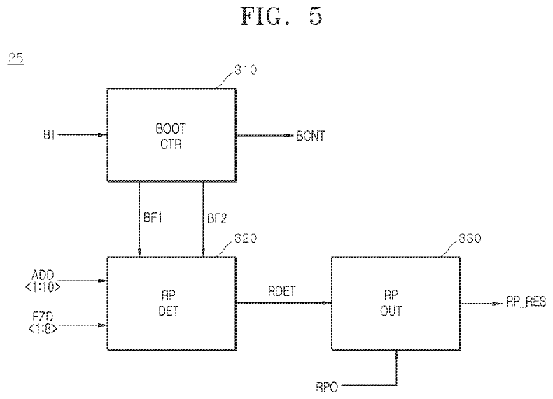

The first rupture operation RUPTURE and the second rupture operation RUPTURE may be operations that are consecutively performed, and may mean the same operation. The first bootup operation BOOT UP and the second bootup operation BOOT UP may be operations that are consecutively performed, and may mean the same operation. The first rupture operation RUPTURE may be performed before the first bootup operation BOOT UP is performed. The second rupture operation RUPTURE may be performed before the second bootup operation BOOT UP is performed. FIG. 5 is a block diagram illustrating a construction according to an embodiment of the repair control circuit 25 that is included in the electronic device 20. The repair control circuit 25 may include a bootup control circuit (BGOOT CTR) 310, a repair detection circuit (RP CTR) 320, and a repair result signal output circuit (RP OUT) 330.

The bootup control circuit 310 may generate the bootup counting signal BCNT that includes a pulse that is periodically generated after the start of first and second bootup operations. The bootup control circuit 310 may generate the bootup counting signal BCNT that includes a pulse that is periodically generated when the bootup signal BT is input. The bootup control circuit 310 may generate the first bootup flag BF1 that is enabled during a first bootup operation period. The bootup control circuit 310 may generate a second bootup flag BF2 that is enabled during a second bootup operation period.

The repair detection circuit 320 may generate a repair detection signal RDET by comparing the address ADD<1:10> and the first fuse data FZD<1:8> during a period in which the first bootup flag BF1 is enabled after the start of a first bootup operation. The repair detection circuit 320 may generate the repair detection signal RDET by comparing the address ADD<1:10> and the second fuse data FZD<1:8> during a period in which the second bootup flag BF2 is enabled after the start of a second bootup operation.

The repair result signal output circuit 330 may output the repair detection signal RDET as the repair result signal RP_RES after the start of a rupture detection operation. The repair result signal output circuit 330 may output the repair detection signal RDET as the repair result signal RP_RES when the repair output signal RPO is enabled. According to an embodiment, the repair result signal output circuit 330 may be implemented to include a plurality of registers and may store the repair detection signal RDET. According to an embodiment, the repair result signal output circuit 330 may output, as the repair result signal RP_RES, the repair detection signal RDET that has been stored in the plurality of registers after the start of a common mode register read (MRR) operation.

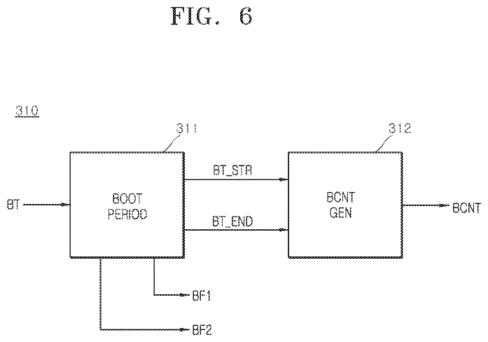

FIG. 6 is a block diagram illustrating a construction according to an embodiment of the bootup control circuit 310 that is included in the repair control circuit 25. The bootup control circuit 310 may include a bootup period control circuit (BOOT PERIOD) 311 and a bootup counting signal generation circuit (BCNT GEN) 312.

The bootup period control circuit 311 may generate a bootup start signal BT_STR that is enabled when the bootup signal BT is input. The bootup period control circuit 311 may generate the bootup start signal BT_STR that is enabled when the bootup signal BT is input after the start of a first bootup operation. The bootup period control circuit 311 may generate the bootup start signal BT_STR that is enabled when the bootup signal BT is input after the start of a second bootup operation. The bootup period control circuit 311 may generate a bootup end signal BT_END that is enabled at timing at which the first bootup operation period is terminated. The bootup period control circuit 311 may generate the bootup end signal BT_END that is enabled at timing at which the second bootup operation period is terminated after the start of the second bootup operation. A period from the timing at which the bootup start signal BT_STR is generated to the timing at which the bootup end signal BT_END is generated may be set as a first and second bootup operation period. The first and second bootup operation period may be set as the time for which all of the fuse data FZD<1:8> that have been stored in the plurality of fuses FS that are included in the fuse circuit 24 are output. The bootup period control circuit 311 may generate the first bootup flag BF1 that is enabled when the bootup signal BT is input after the start of the first bootup operation. The bootup period control circuit 311 may generate the second bootup flag BF2 that is enabled when the bootup signal BT is input after the start of the second bootup operation.

The bootup counting signal generation circuit 312 may generate the bootup counting signal BCNT based on the bootup start signal BT_STR and the bootup end signal BT_END. The bootup counting signal generation circuit 312 may generate the bootup counting signal BCNT that includes a pulse that is periodically generated from timing at which the bootup start signal BT_STR is enabled to timing at which the bootup end signal BT_END is enabled.

FIG. 7 is a block diagram illustrating a construction according to an embodiment of the repair detection circuit 320 that is included in the repair control circuit 25. The repair detection circuit 320 may include an address latch circuit (ADD LAT) 321, a target period signal generation circuit (TR GEN) 322, an address comparison circuit (ADD CMP) 323, and a repair detection signal generation circuit (RDET GEN) 324.

The address latch circuit 321 may latch the address ADD<1:8> that is input during a first bootup operation period. The address latch circuit 321 may generate a first row address RA<1:8> from the address ADD<1:8> that is latched during the first bootup operation period. The address latch circuit 321 may latch the address ADD<1:8> that is input during a second bootup operation period. The address latch circuit 321 may generate a second row address RA<1:8> from the address ADD<1:8> that is latched during the second bootup operation period. The first row address RA<1:8> may mean a signal that is generated from the address ADD<1:8> that is input during the first bootup operation period. The second row address RA<1:8> may mean a signal that is generated from the address ADD<1:8> that is input during the second bootup operation period. The address ADD<1:8> that is input during the first bootup operation period may be input to have a logic level combination for selecting a memory cell MC having a fail that has occurred. The address ADD<1:8> that is input during the second bootup operation period may be input to have a logic level combination for selecting a memory cell MC having a fail that has occurred. The address ADD<1:8> that is input during the first bootup operation period and the address ADD<1:8> that is input during the second bootup operation period may be input to have the same logic level combination. The first row address RA<1:8> that is generated during the first bootup operation period and the second row address RA<1:8> that is generated during the second bootup operation period may be generated to have the same logic level combination.

The target period signal generation circuit 322 may generate a target period signal TR based on the address ADD<9:10>. The target period signal generation circuit 322 may generate the target period signal TR that is enabled when the address ADD<9:10> have a logic level combination for activating the first bank (231 in FIG. 3). The target period signal generation circuit 322 may generate the target period signal TR that is enabled when the address ADD<9:10> has a logic level combination for activating the second bank (232 in FIG. 3). The target period signal generation circuit 322 may generate the target period signal TR that is enabled when the address ADD<9:10> has a logic level combination for activating the third bank (233 in FIG. 3). The target period signal generation circuit 322 may generate the target period signal TR that is enabled when the address ADD<9:10> has a logic level combination for activating the fourth bank (234 in FIG. 3).

The address comparison circuit 323 may generate the comparison signal CMP by comparing first and second row addresses RA<1:8> and the first and second fuse data FZD<1:8> during a period in which the target period signal TR is enabled. The address comparison circuit 323 may generate the comparison signal CMP that is enabled when the first row address RA<1:8> and the first fuse data FZD<1:8> have the same logic level combination during a period in which the target period signal TR is enabled after the start of a first bootup operation. The address comparison circuit 323 may generate the comparison signal CMP that is enabled when the second row address RA<1:8> and the second fuse data FZD<1:8> have the same logic level combination during a period in which the target period signal TR is enabled after the start of a second bootup operation.

The repair detection signal generation circuit 324 may generate the repair detection signal RDET based on the comparison signal CMP during the period in which the first bootup flag BF1 is enabled. The repair detection signal generation circuit 324 may generate the repair detection signal RDET based on the comparison signal CMP during a period in which the second bootup flag BF2 is enabled.

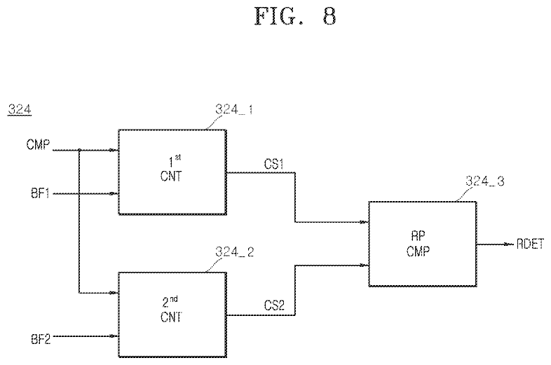

FIG. 8 is a block diagram illustrating a construction according to an embodiment of the repair detection signal generation circuit 324 that is included in the repair detection circuit 320. The repair detection signal generation circuit 324 may include a first counting circuit (1^{st} CNT) 324_1, a second counting circuit (2^{nd} CNT) 324_2, and a repair comparison circuit (RP CMP) 324_3.

The first counting circuit 324_1 may generate a first counting signal CS1 based on the comparison signal CMP during a period in which the first bootup flag BF1 is enabled. The first counting circuit 324_1 may generate the first counting signal CS1 that is toggled whenever the comparison signal CMP is enabled to a logic high level during the period in which the first bootup flag BF1 is enabled.

The second counting circuit 324_2 may generate the second counting signal CS2 based on the comparison signal CMP during a period in which the second bootup flag BF2 is enabled. The second counting circuit 324_2 may generate the second counting signal CS2 that is toggled whenever the comparison signal CMP is enabled to a logic high level during the period in which the second bootup flag BF2 is enabled.

The repair comparison circuit 324_3 may generate the repair detection signal RDET by comparing the first counting signal CS1 and the second counting signal CS2. The repair comparison circuit 324_3 may generate the repair detection signal RDET having a logic high level when the first counting signal CS1 and the second counting signal CS2 have different logic levels. The repair comparison circuit 324_3 may generate the repair detection signal RDET having a logic low level when the first counting signal CS1 and the second counting signal CS2 have the same logic level.

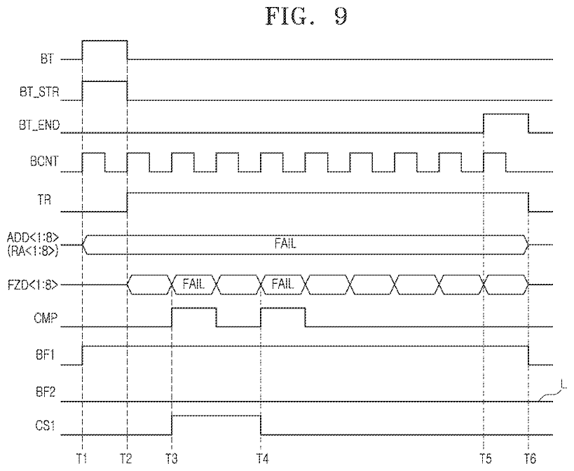

FIG. 9 is a timing diagram for describing a first bootup operation of the electronic system according to an embodiment of the present disclosure. The first bootup operation according to an embodiment of the present disclosure may be described with reference to FIG. 9. In this case, a case in which the plurality of fuses (FS in FIG. 4) that are included in the fuse circuit 24 has been ruptured twice after the start of a first rupture operation so that the plurality of fuses has the same combination as the address ADD<1:8> for selecting a memory cell having a fail that has occurred may be described as follows as an example.

Prior to the description, the controller 10 may output the command CMD<1:3> and the address ADD<1:10> for performing the first bootup operation. The first to eighth bits ADD<1:8> of the address ADD<1:10> may be output to have the same logic level combination FAIL as the fail address FAIL<1:8> for selecting a memory cell having a fail that has occurred.

At timing T1, the command decoder 21 may generate the bootup signal BT that is enabled to a logic high level when the command CMD<1:3> that is input in synchronization with the clock CLK has a logic level combination for performing a bootup operation.

The bootup period control circuit 311 of the bootup control circuit 310 may generate the bootup start signal BT_STR that is enabled to a logic high level when the bootup signal BT is input. The bootup counting signal generation circuit 312 of the bootup control circuit 310 may generate the bootup counting signal BCNT that includes a pulse that is periodically generated from timing at which the bootup start signal BT_STR is enabled.

The address latch circuit 321 of the repair detection circuit 320 may latch the address ADD<1:8> that is input during a first bootup operation period. The address latch circuit 321 may generate the first row address RA<1:8> from the address ADD<1:8> that has been latched during the first bootup operation period. The first row address RA<1:8> may be generated to have the logic level combination FAIL for selecting a memory cell having a fail that has occurred.

The bootup period control circuit 311 of the bootup control circuit 310 may generate the first bootup flag BF1 that is enabled to a logic high level when the bootup signal BT is input after the start of the first bootup operation. The bootup period control circuit 311 may generate the second bootup flag BF2 that is disabled to a logic low level when the bootup signal BT is input after the start of the first bootup operation.

At timing T2, the target period signal generation circuit 322 of the repair detection circuit 320 may generate the target period signal TR that is enabled to a logic high level based on the address ADD<9:10>.

The fuse circuit 24 may sequentially output the first fuse data FZD<1:8> that are generated by the first rupture operation, based on the bootup counting signal BCNT that includes a pulse that is periodically generated after the start of the first bootup operation.

The address comparison circuit 323 of the repair detection circuit 320 may generate the comparison signal CMP having a logic low level by comparing the first row address RA<1:8> and the first fuse data FZD<1:8> during a period in which the target period signal TR is enabled.

At timing T3, the fuse circuit 24 may output the first fuse data FZD<1:8> that are generated by the first rupture operation, based on the bootup counting signal BCNT that includes a pulse that is periodically generated after the start of the first bootup operation. In this case, the first fuse data FZD<1:8> may be generated to have the logic level combination FAIL for selecting a memory cell having a fail that has occurred.

The address comparison circuit 323 of the repair detection circuit 320 may generate the comparison signal CMP having a logic high level by comparing the first row address RA<1:8> and the first fuse data FZD<1:8> during the period in which the target period signal TR is enabled.

The first counting circuit 324_1 of the repair detection signal generation circuit 324 may generate the first counting signal CS1 having a logic high level when the comparison signal CMP having a logic high level is input during a period in which the first bootup flag BF1 is enabled.

At timing T4, the fuse circuit 24 may output the first fuse data FZD<1:8> that are generated by the first rupture operation, based on the bootup counting signal BCNT that includes a pulse that is periodically generated after the start of the first bootup operation. In this case, the first fuse data FZD<1:8> may be generated to have the logic level combination FAIL for selecting a memory cell having a fail that has occurred.

The address comparison circuit 323 of the repair detection circuit 320 may generate the comparison signal CMP having a logic high level by comparing the first row address RA<1:8> and the first fuse data FZD<1:8> during a period in which the target period signal TR is enabled.

The first counting circuit 324_1 of the repair detection signal generation circuit 324 may generate the first counting signal CS1 having a logic low level when the comparison signal CMP having a logic high level is input during the period in which the first bootup flag BF1 is enabled.

At timing T5, the bootup period control circuit 311 of the bootup control circuit 310 may generate the bootup end signal BT_END that is enabled to a logic high level after the first bootup operation period.

At timing T6, the bootup period control circuit 311 may generate the first bootup flag BF1 that is disabled to a logic low level after the first bootup operation is completed.

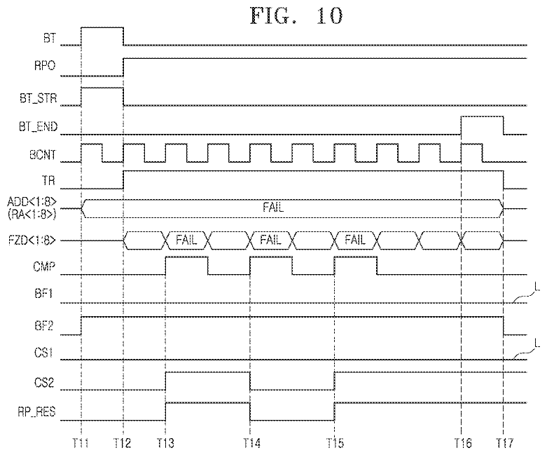

FIG. 10 is a timing diagram for describing a second bootup operation of the electronic system according to an embodiment of the present disclosure. The second bootup operation according to an embodiment of the present disclosure may be described with reference to FIG. 10. In this case, a case in which the plurality of fuses (FS in FIG. 4) that are included in the fuse circuit 24 has been additionally ruptured after the start of the second rupture operation after the first bootup operation so that the plurality of fuses has the same combination as the address ADD<1:8> for selecting a memory cell having a fail that has occurred and may be described as follows as an example.

Prior to the description, the controller 10 may output the command CMD<1:3> for performing a rupture detection operation after outputting the command CMD<1:3> and the address ADD<1:10> for performing the second bootup operation. The first to eighth bits ADD<1:8> of the address ADD<1:10> may be output to have the logic level combination FAIL for selecting a memory cell having a fail that has occurred.

At timing T11, the command decoder 21 may generate the bootup signal BT that is enabled to a logic high level when the command CMD<1:3> that is input in synchronization with the clock CLK has a logic level combination for performing a bootup operation.

The bootup period control circuit 311 of the bootup control circuit 310 may generate the bootup start signal BT_STR that is enabled to a logic high level when the bootup signal BT is input. The bootup counting signal generation circuit 312 of the bootup control circuit 310 may generate the bootup counting signal BCNT that includes a pulse that is periodically generated, from timing at which the bootup start signal BT_STR is enabled.

The address latch circuit 321 of the repair detection circuit 320 may latch the address ADD<1:8> that is input during the second bootup operation period. The address latch circuit 321 may generate the second row address RA<1:8> from the address ADD<1:8> that has been latched during the second bootup operation period. The second row address RA<1:8> may be generated to have the logic level combination FAIL for selecting a memory cell having a fail that has occurred.

The bootup period control circuit 311 of the bootup control circuit 310 may generate the second bootup flag BF2 that is enabled to a logic high level when the bootup signal BT is input, after the start of the second bootup operation. The bootup period control circuit 311 may generate the first bootup flag BF1 that is disabled to a logic low level when the bootup signal BT is input after the start of the second bootup operation.

At timing T12, the command decoder 21 may generate the repair output signal RPO that is enabled to a logic high level when the command CMD<1:3> that is input in synchronization with the clock CLK has a logic level combination for performing a rupture detection operation.

The target period signal generation circuit 322 of the repair detection circuit 320 may generate the target period signal TR that is enabled to a logic high level based on the address ADD<9:10>.

The fuse circuit 24 may sequentially output the second fuse data FZD<1:8> that are generated by the second rupture operation, based on the bootup counting signal BCNT that includes a pulse that is periodically generated after the start of the second bootup operation.

The address comparison circuit 323 of the repair detection circuit 320 may generate the comparison signal CMP having a logic low level by comparing the second row address RA<1:8> and the second fuse data FZD<1:8> during a period in which the target period signal TR is enabled.

At timing T13, the fuse circuit 24 may output the second fuse data FZD<1:8> that are generated by the second rupture operation, based on the bootup counting signal BCNT that includes a pulse that is periodically generated after the start of the second bootup operation. In this case, the second fuse data FZD<1:8> may be generated to have the logic level combination FAIL for selecting a memory cell having a fail that has occurred.

The address comparison circuit 323 of the repair detection circuit 320 may generate the comparison signal CMP having a logic high level by comparing the second row address RA<1:8> and the second fuse data FZD<1:8> during the period in which the target period signal TR is enabled.

The first counting circuit 324_1 of the repair detection signal generation circuit 324 may generate the first counting signal CS1 having a logic low level during a period in which the first bootup flag BF1 is disabled. The second counting circuit 324_2 of the repair detection signal generation circuit 324 may generate the second counting signal CS2 having a logic high level when the comparison signal CMP is enabled to a logic high level during a period in which the second bootup flag BF2 is enabled. The repair comparison circuit 324_3 of the repair detection signal generation circuit 324 may generate the repair detection signal RDET having a logic high level when the first counting signal CS1 and the second counting signal CS2 have different logic levels.

The repair result signal output circuit 330 may output the repair detection signal RDET as the repair result signal RP_RES when the repair output signal RPO is enabled to a logic high level.

At timing T14, the fuse circuit 24 may output the second fuse data FZD<1:8> that are generated by the second rupture operation, based on the bootup counting signal BCNT that includes a pulse that is periodically generated after the start of the second bootup operation. In this case, the second fuse data FZD<1:8> may be generated to have the logic level combination FAIL for selecting a memory cell having a fail that has occurred.

The address comparison circuit 323 of the repair detection circuit 320 may generate the comparison signal CMP having a logic high level by comparing the first row address RA<1:8> and the first fuse data FZD<1:8> during the period in which the target period signal TR is enabled.

The first counting circuit 324_1 of the repair detection signal generation circuit 324 may generate the first counting signal CS1 having a logic low level during the period in which the first bootup flag BF1 is disabled. The second counting circuit 324_2 of the repair detection signal generation circuit 324 may generate the second counting signal CS2 having a logic low level when the comparison signal CMP is enabled to a logic high level during the period in which the second bootup flag BF2 is enabled. The repair comparison circuit 324_3 of the repair detection signal generation circuit 324 may generate the repair detection signal RDET having a logic low level when the first counting signal CS1 and the second counting signal CS2 have the same logic level.

The repair result signal output circuit 330 may output the repair detection signal RDET as the repair result signal RP_RES when the repair output signal RPO is enabled to a logic high level.

At timing T15, the fuse circuit 24 may output the second fuse data FZD<1:8> that are generated by the second rupture operation, based on the bootup counting signal BCNT that includes a pulse that is periodically generated after the start of the second bootup operation. In this case, the second fuse data FZD<1:8> may be generated to have the logic level combination FAIL for selecting a memory cell having a fail that has occurred.

The address comparison circuit 323 of the repair detection circuit 320 may generate the comparison signal CMP having a logic high level by comparing the second row address RA<1:8> and the second fuse data FZD<1:8> during the period in which the target period signal TR is enabled.

The first counting circuit 324_1 of the repair detection signal generation circuit 324 may generate the first counting signal CS1 having a logic low level during the period in which the first bootup flag BF1 is disabled. The second counting circuit 324_2 of the repair detection signal generation circuit 324 may generate the second counting signal CS2 having a logic high level when the comparison signal CMP is enabled to a logic high level during the period in which the second bootup flag BF2 is enabled. The repair comparison circuit 324_3 of the repair detection signal generation circuit 324 may generate the repair detection signal RDET having a logic high level when the first counting signal CS1 and the second counting signal CS2 have different logic levels.

The repair result signal output circuit 330 may output the repair detection signal RDET as the repair result signal RP_RES when the repair output signal RPO is enabled to a logic high level.

At timing T16, the bootup period control circuit 311 of the bootup control circuit 310 may generate the bootup end signal BT_END that is enabled to a logic high level after the second bootup operation period.

At timing T17, the bootup period control circuit 311 may generate the second bootup flag BF2 that is disabled to a logic low level after the second bootup operation is completed.

The controller 10 may detect that a rupture operation is additionally performed after the first bootup operation by receiving the repair result signal RP_RES having a logic high level.

In the electronic system 1 according to an embodiment of the present disclosure, the electronic device 20 can compare a row address for selecting a memory cell having an error that has occurred after the start of a bootup operation and fuse data that are generated by a rupture operation. The controller 10 can detect the results of the rupture operation based on a result of the comparison. In the electronic system 1, the electronic device 20 can compare a row address for selecting a memory cell having an error that has occurred after the start of a bootup operation and fuse data that are generated by a rupture operation. The controller 10 can detect whether a rupture operation is additionally performed between bootup operations that are consecutively performed by detecting a result of the comparison.

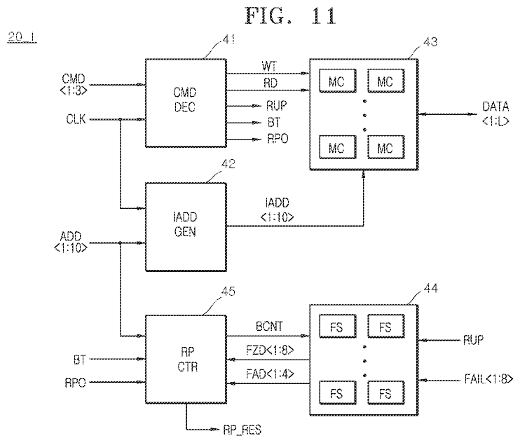

FIG. 11 is a block diagram illustrating a construction according to another embodiment of the electronic device 20 that is included in the electronic system 1. An electronic device 20_1 may include a command decoder (CMD DEC) 41, an internal address generation circuit (IADD GEN) 42, a memory circuit 43, a fuse circuit 44, and a repair control circuit (RP CTR) 45.

The command decoder 41 may generate a write signal WT, a read signal RD, a rupture signal RUP, a bootup signal BT, and a repair output signal RPO by decoding a command CMD<1:3> in synchronization with a clock CLK. The command decoder 41 may generate the write signal WT that is enabled when the command CMD<1:3> that is input in synchronization with the clock CLK having a logic level combination for performing a write operation. The command decoder 41 may generate the read signal RD that is enabled when the command CMD<1:3> that is input in synchronization with the clock CLK has a logic level combination for performing a read operation. The command decoder 41 may generate the rupture signal RUP that is enabled when the command CMD<1:3> that is input in synchronization with the clock CLK has a logic level combination for performing a rupture operation. The command decoder 41 may generate the bootup signal BT that is enabled when the command CMD<1:3> that is input in synchronization with the clock CLK has a logic level combination for performing first and second bootup operations. The command decoder 41 may generate the repair output signal RPO that is enabled when the command CMD<1:3> that is input in synchronization with the clock CLK has a logic level combination for performing a rupture detection operation. The number of bits of the command CMD<1:3> has been set to “3”, but may be set as various numbers of bits in order to generate various signals.

The internal address generation circuit 42 may generate an internal address IADD<1:10> by buffering an address ADD<1:10> in synchronization with the clock CLK. First to eighth bits IADD<1:8> of the internal address may be set as bits for selecting a plurality of memory cells that are included in the memory circuit 43. Ninth and tenth bits IADD<9:10> of the internal address may be set as bits for selecting the first to fourth banks (231 to 234 in FIG. 3) that are included in the memory circuit 43. The number of bits of each of the address ADD<1:10> and the internal address IADD<1:10> has been set to “10”, but may be set as various numbers of bits in order to select various numbers of memory cells MC.

The memory circuit 43 may include a plurality of memory cells MC. The memory circuit 43 may store data DATA<1:L> in a memory cell MC that is selected based on the internal address IADD<1:10> when the write signal WT is generated. The memory circuit 43 may output the data DATA<1:L> that have been stored in the memory cell MC that is selected based on the internal address IADD<1:10> when the read signal RD is generated. The number of bits of the data DATA<1:L> may be set as “L”. “L” may be set as a positive integer. According to an embodiment, the number of bits of the data may be variously set like “8”, “16”, or “32” etc. A case in which the number of bits of the data is “8” may mean a case in which the number of bits of data that are input and output after the start of one write and read operation is 8. The memory circuit 43 may be implemented to have the same construction as the memory circuit 23 illustrated in FIG. 3 and may perform the same operation as the memory circuit 43, and thus a detailed description thereof is omitted.

The fuse circuit 44 may include a plurality of fuses FS. The fuse circuit 44 may rupture the plurality of fuses FS in order to generate fuse data FZD<1:8> having the same combination as a fail address FAIL<1:8> for selecting a memory cell having a fail that has occurred, among the plurality of memory cells MC, when a rupture signal RUP is enabled. The fuse circuit 44 may output first and second fuse data FZD<1:8> that are generated by first and second rupture operations, based on a bootup counting signal BCNT that includes a pulse that is periodically generated after the start of first and second bootup operations. The fuse circuit 44 may output the first and second fuse address FAD<1:4>, that is, information with regard to locations at which the first and second fuse data FZD<1:8> have been stored after the start of the first and second bootup operations. If the plurality of fuses FS has already been ruptured by the fail address FAIL<1:8> after the start of the first bootup operation, the fuse circuit 44 may generate the first fuse data (FZD<1:8> in FIG. 2) by rupturing a plurality of new fuses FS without using the plurality of fuses FS that have already been ruptured. The fuse circuit 44 may output the second fuse data (FZD<1:8> in FIG. 2) that are generated as the plurality of new fuses FS is ruptured after the start of the second bootup operation. The number of bits of the fuse data FZD<1:8> may be set to “8”. The number of bits of the fuse data FZD<1:8> and the number of bits of the address ADD<1:8> for selecting a plurality of memory cells that are included in the memory circuit 43 may be identically set. The first fuse data FZD<1:8 may mean fuse data that are output after the start of the first bootup operation. The second fuse data FZD<1:8> may mean fuse data that are output after the start of the second bootup operation. The number of bits of the fuse address FAD<1:4> may be set to “4”. The first fuse address FAD<1:4> may mean a fuse address that is output after the start of the first bootup operation. The second fuse address FAD<1:4> may mean a fuse address that is output after the start of the second bootup operation. The first and second rupture operations may each be set as an operation of electrically cutting the plurality of fuses FS in order to generate the fuse data FZD<1:8> having the same logic level combination as the internal address IADD<1:8> for selecting a memory cell MC having a fail that has occurred.

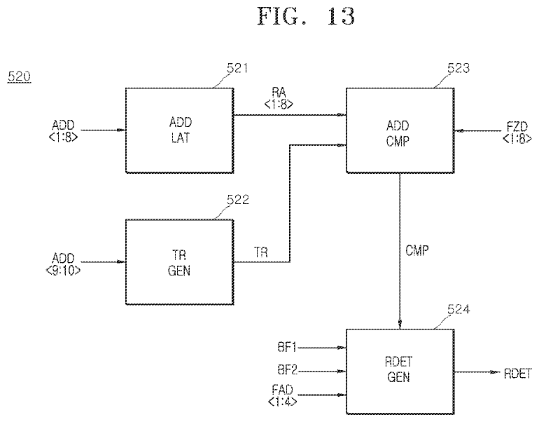

The repair control circuit 45 may generate the bootup counting signal BCNT that includes a pulse that is periodically generated after the start of first and second bootup operations. The repair control circuit 45 may generate a comparison signal (CMP in FIG. 13) by comparing the address ADD<1:8> that is input after the start of the first and second bootup operations and the fuse data FZD<1:8>. The repair control circuit 45 may generate a repair result signal RP_RES based on the comparison signal (CMP in FIG. 13) and the first and second fuse addresses FAD<1:4>. The repair control circuit 45 may output the repair result signal RP_RES to the controller 10 when the repair output signal RPO is enabled after the start of a rupture detection operation.

The electronic device 20_1 may store the data DATA<1:L> in the memory cell MC that is selected based on the command CMD<1:3> and the address ADD<1:10> after the start of a write operation. The electronic device 20_1 may output the data DATA<1:L> that have been stored in the memory cell MC that is selected based on the command CMD<1:3> and the address ADD<1:10> after the start of a read operation. The electronic device 20_1 may rupture the plurality of fuses FS in order to generate the fuse data FZD<1:8> having the same combination as the fail address FAIL<1:8> for selecting a memory cell having a fail that has occurred after the start of a rupture operation. The electronic device 20_1 may sequentially output the fuse data FZD<1:8> that have been stored in the fuse FS by a rupture operation RUPTURE and the fuse address FAD<1:4> after the start of a bootup operation. The electronic device 20_1 may generate the comparison signal (CMP in FIG. 13) by comparing the address ADD<1:10> that is input after the start of a bootup operation and the fuse data FZD<1:8>, and may generate the repair result signal RP_RES based on the comparison signal (CMP in FIG. 13) and the fuse address FAD<1:4>. The electronic device 20_1 may output the repair result signal RP_RES to the controller 10 after the start of a rupture detection operation.

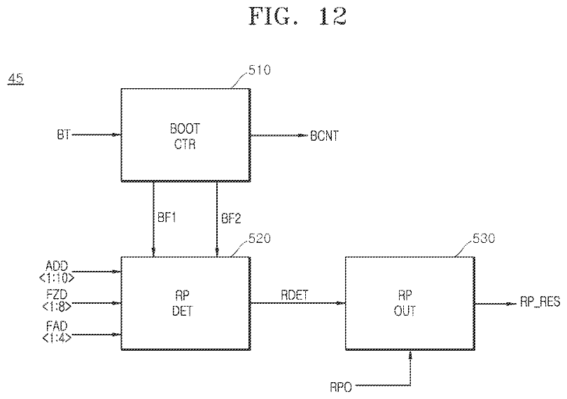

FIG. 12 is a block diagram illustrating a construction according to an embodiment of the repair control circuit 45 that is included in the electronic device 20_1. The repair control circuit 45 may include a bootup control circuit (BOOT CTR) 510, a repair detection circuit (RP DET) 520, and a repair result signal output circuit (RP OUT) 530.

The bootup control circuit 510 may generate the bootup counting signal BCNT that includes a pulse that is periodically generated after the start of first and second bootup operations. The bootup control circuit 510 may generate the bootup counting signal BCNT that includes a pulse that is periodically generated when the bootup signal BT is input. The bootup control circuit 510 may generate a first bootup flag BF1 that is enabled during a first bootup operation period. The bootup control circuit 510 may generate a second bootup flag BF2 that is enabled during a second bootup operation period. The bootup control circuit 510 may be implemented to have the same construction as the bootup control circuit 310 illustrated in FIG. 6 and may perform the same operation as the bootup control circuit 310, and thus a detailed description thereof is omitted.

The repair detection circuit 520 may generate a repair detection signal RDET, based on the address ADD<1:10>, the first fuse data FZD<1:8>, and the first fuse address FAD<1:4> during a period in which the first bootup flag BF1 is enabled after the start of a first bootup operation. The repair detection circuit 520 may generate the repair detection signal RDET by comparing the address ADD<1:10>, the second fuse data FZD<1:8>, and the second fuse address FAD<1:4> during a period in which the second bootup flag BF2 is enabled after the start of a second bootup operation.

The repair result signal output circuit 530 may output the repair detection signal RDET as the repair result signal RP_RES after the start of a rupture detection operation. The repair result signal output circuit 530 may output the repair detection signal RDET as the repair result signal RP_RES when the repair output signal RPO is enabled. According to an embodiment, the repair result signal output circuit 530 may be implemented to include a plurality of registers, and may store the repair detection signal RDET. According to an embodiment, the repair result signal output circuit 530 may output, as the repair result signal RP_RES, the repair detection signal RDET that has been stored in the plurality of registers after the start of a common mode register read (MRR) operation.

FIG. 13 is a block diagram illustrating a construction according to an embodiment of the repair detection circuit 520 that is included in the repair control circuit 45. The repair detection circuit 520 may include an address latch circuit (ADD LAT) 521, a target period signal generation circuit (TR GEN) 522, an address comparison circuit (ADD CMP) 523, and a repair detection signal generation circuit (RDET GEN) 524.

The address latch circuit 521 may latch the address ADD<1:8> that is input during a first bootup operation period. The address latch circuit 521 may generate a first row address RA<1:8> from the address ADD<1:8> that has been latched during the first bootup operation period. The address latch circuit 521 may latch the address ADD<1:8> that is input during a second bootup operation period. The address latch circuit 521 may generate a second row address RA<1:8> from the address ADD<1:8> that has been latched during the second bootup operation period. The first row address RA<1:8> may mean a signal that is generated from the address ADD<1:8> that is input during the first bootup operation period. The second row address RA<1:8> may mean a signal that is generated from the address ADD<1:8> that is input during the second bootup operation period. The address ADD<1:8> that is input during the first bootup operation period may be input to have a logic level combination for selecting a memory cell MC having a fail that has occurred. The address ADD<1:8> that is input during the second bootup operation period may be input to have a logic level combination for selecting a memory cell MC having a fail that has occurred. The address ADD<1:8> that is input during the first bootup operation period and the address ADD<1:8> that is input during the second bootup operation period may be input to have the same logic level combination. The first row address RA<1:8> that is generated during the first bootup operation period and the second row address RA<1:8> that is generated during the second bootup operation period may be generated to have the same logic level combination.

The target period signal generation circuit 522 may generate a target period signal TR based on the address ADD<9:10>. The target period signal generation circuit 522 may generate the target period signal TR that is enabled when the address ADD<9:10> has a logic level combination for activating the first bank (231 in FIG. 3). The target period signal generation circuit 522 may generate the target period signal TR that is enabled when the address ADD<9:10> has a logic level combination for activating the second bank (232 in FIG. 3). The target period signal generation circuit 522 may generate the target period signal TR that is enabled when the address ADD<9:10> has a logic level combination for activating the third bank (233 in FIG. 3). The target period signal generation circuit 522 may generate the target period signal TR that is enabled when the address ADD<9:10> has a logic level combination for activating the fourth bank (234 in FIG. 3).

The address comparison circuit 523 may generate the comparison signal CMP by comparing the first and second row addresses RA<1:8> and the first and second fuse data FZD<1:8> during a period in which the target period signal TR is enabled. The address comparison circuit 523 may generate the comparison signal CMP that is enabled when the first row address RA<1:8> and the first fuse data FZD<1:8> have the same logic level combination during a period in which the target period signal TR is enabled after the start of a first bootup operation. The address comparison circuit 523 may generate the comparison signal CMP that is enabled when the second row address RA<1:8> and the second fuse data FZD<1:8> have the same logic level combination during a period in which the target period signal TR is enabled after the start of a second bootup operation.

The repair detection signal generation circuit 524 may generate the repair detection signal RDET based on the comparison signal CMP and the first fuse address FAD<1:4> during a period in which the first bootup flag BF1 is enabled. The repair detection signal generation circuit 524 may generate the repair detection signal RDET based on the comparison signal CMP and the second fuse address FAD<1:4> during a period in which the second bootup flag BF2 is enabled.

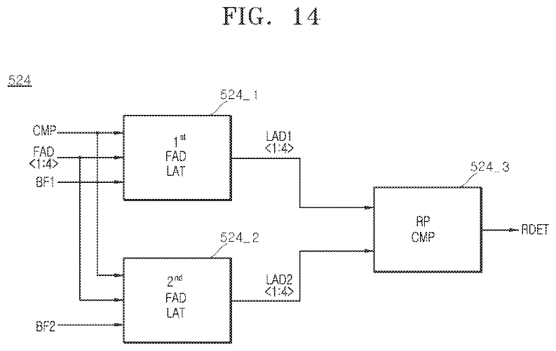

FIG. 14 is a block diagram illustrating a construction according to an embodiment of the repair detection signal generation circuit 524 that is included in the repair detection circuit 520. The repair detection signal generation circuit 524 may include a first fuse address latch circuit (1^{st} FAD LAT) 524_1, a second fuse address latch circuit (2^{nd} FAD LAT) 524_2, and a repair comparison circuit (RP CMP) 524_3.

The first fuse address latch circuit 524_1 may latch the first fuse address FAD<1:4> when the comparison signal CMP is enabled during a period in which the first bootup flag BF1 is enabled. The first fuse address latch circuit 524_1 may output, as a first latch address LAD1<1:4>, the first fuse address FAD<1:4> that has been latched.

The second fuse address latch circuit 524_2 may latch the second fuse address FAD<1:4> when the comparison signal CMP is enabled during a period in which the second bootup flag BF2 is enabled. The second fuse address latch circuit 524_2 may output, as a second latch address LAD2<1:4>, the second fuse address FAD<1:4> that has been latched.

The repair comparison circuit 524_3 may generate the repair detection signal RDET by comparing the first latch address LAD1<1:4> and the second latch address LAD2<1:4>. The repair comparison circuit 524_3 may generate the repair detection signal RDET having a logic high level when the first latch address LAD1<1:4> and the second latch address LAD2<1:4> have different logic levels. The repair comparison circuit 524_3 may generate the repair detection signal RDET having a logic low level when the first latch address LAD1<1:4> and the second latch address LAD2<1:4> have the same logic level. The repair comparison circuit 524_3 may generate the repair detection signal RDET having a logic high level when the first latch address LAD1<1:4> and the second latch address LAD2<1:4> have different logic levels as a rupture operation RUPTURE is additionally performed. The repair comparison circuit 524_3 may generate the repair detection signal RDET having a logic low level when the first latch address LAD1<1:4> and the second latch address LAD2<1:4> have the same logic level because a rupture operation RUPTURE is not additionally performed.

As described above, in the electronic system 1 according to another embodiment of the present disclosure, the electronic device 20_1 can compare a row address for selecting a memory cell having an error that has occurred after the start of a bootup operation and fuse data that are generated by a rupture operation. The controller 10 can detect the results of the rupture operation based on a result of the comparison. In the electronic system 1, the electronic device 20_1 can compare a row address for selecting a memory cell having an error that has occurred after the start of a bootup operation and fuse data that are generated by a rupture operation. The controller 10 can detect whether a rupture operation is additionally performed between bootup operations that are consecutively performed by detecting a result of the comparison.

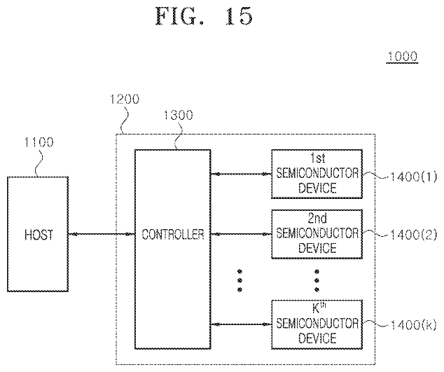

FIG. 15 is a diagram illustrating a construction according to an embodiment of an electronic system 1000 according to an embodiment of the present disclosure. As illustrated in FIG. 15, the electronic system 1000 may include a host HOST 1100 and a semiconductor system 1200.

The host 1100 and the semiconductor system 1200 may mutually transmit signals by using an interface protocol. The interface protocol that is used between the host 1100 and the semiconductor system 1200 may include a multi-media card (MMC), an enhanced small disk interface (ESDI), integrated drive electronics (IDE), peripheral component interconnect-express (PCI-E), advanced technology attachment (ATA), serial ATA (SATA), parallel ATA (PATA), a serial attached SCSI (SAS), and a universal serial bus (USB).

The semiconductor system 1200 may include a controller 1300 and semiconductor devices 1400(K:1). The controller 1300 may control the semiconductor devices 1400(K:1) so that the semiconductor devices 1400(K:1) perform a write operation, a read operation, a bootup operation, and a rupture detection operation. Each of the semiconductor devices 1400(K:1) may compare a row address for selecting a memory cell having an error occurring after the start of a bootup operation and fuse data that are generated by a rupture operation, and may provide the results of a rupture operation to the controller 1300 based on a result of the comparison. The controller 1300 may detect whether a rupture operation is additionally performed between bootup operations that are consecutively performed by receiving the results of the rupture operation after the start of a rupture detection operation.

The controller 1300 may be implemented as the controller 10 illustrated in FIG. 1. Each of the semiconductor devices 1400(K:1) may be implemented as the electronic device 20 illustrated in FIG. 2 or the electronic device 20_1 illustrated in FIG. 11. According to an embodiment, each of the semiconductor devices 1400(1:K) may be implemented as one of dynamic random access memory (DRAM), phase change random access memory (PRAM), resistive random access memory (RRAM), magnetic random access memory (MRAM), and ferroelectric random access memory (FRAM) etc.

What is claimed is:

1. An electronic device comprising:
a first counting circuit configured to receive a comparison signal to generate a first counting signal based on the comparison signal, the comparison signal generated by comparing a first row address after a start of a first bootup operation and first fuse data, the first fuse data generated by a first rupture operation;
a second counting circuit configured to receive the comparison signal to generate a second counting signal based on the comparison signal, the comparison signal generated by comparing a second row address after a start of a second bootup operation and second fuse data, the second fuse data generated by a second rupture operation; and
a repair comparison circuit configured to receive the first and second counting signals to generate a repair detection signal for detecting whether the first and second rupture operations are additionally performed by comparing the first counting signal with the second counting signal and the repair comparison circuit is configured to output the repair detection signal.

2. The electronic device of claim 1, wherein the first row address that is input after the start of the first bootup operation and the second row address that is input after the start of the second bootup operation have an identical logic level combination.

3. The electronic device of claim 1, wherein the comparison signal is a signal that is enabled when the first row address and the first fuse data have an identical logic level combination after the start of the first bootup operation and that is enabled when the second row address and the second fuse data have an identical logic level combination after the start of the second bootup operation.

4. The electronic device of claim 1, further comprising a fuse circuit comprising a plurality of fuses and configured to generate the first fuse data and the second fuse data by performing the first and second rupture operations on the plurality of fuses based on a fail address.

5. The electronic device of claim 4, wherein each of the first and second rupture operations is an operation of electrically cutting the plurality of fuses in order to generate the first fuse data and the second fuse data having a logic level identical with a logic level of the fail address.

6. The electronic device of claim 4, wherein:
the fuse circuit is configured to generate the first fuse data by performing the first rupture operation on the plurality of fuses based on the fail address prior to the first bootup operation and to output the first fuse data after the start of the first bootup operation, and
the fuse circuit is configured to generate the second fuse data by performing the second rupture operation on the plurality of fuses based on the fail address prior to the second bootup operation and to output the second fuse data after the start of the second bootup operation.

7. An electronic device comprising:
a repair control circuit configured to receive a bootup signal to generate a bootup counting signal comprising a pulse that is periodically generated after a start of first and second bootup operations, configured to generate a comparison signal after comparing first and second row addresses that are received by the repair control circuit after the start of the first and second bootup operations and the generation of first and second fuse data, configured to generate a repair result signal for detecting whether first and second rupture operations are additionally performed based on the comparison signal, and configured to output the repair result signal to an outside of the electronic device when a repair output signal is received by the repair control circuit; and
a fuse circuit configured to output the first and second fuse data, the first and second fuse data generated by the first and second rupture operations based on the bootup counting signal.

8. The electronic device of claim 7, wherein the first row address that is input after the start of the first bootup operation and the second row address that is input after the start of the second bootup operation have an identical logic level combination.

9. The electronic device of claim 7, wherein the comparison signal is a signal that is enabled when the first row address and the first fuse data have an identical logic level combination after the start of the first bootup operation and that is enabled when the second row address and the second fuse data have an identical logic level combination after the start of the second bootup operation.

10. The electronic device of claim 7, wherein the repair control circuit comprises:
a bootup control circuit configured to generate the bootup counting signal comprising a pulse that is periodically generated when the bootup signal is received by the bootup control circuit, configured to generate a first bootup flag that is enabled during a first bootup operation period in response to receiving the bootup signal, and configured to generate a second bootup flag that is enabled during a second bootup operation period in response to receiving the bootup signal;
a repair detection circuit configured to generate a repair detection signal by comparing the first bootup flag, an address during a period in which the second bootup flag is enabled, and the first and second fuse data; and
a repair result signal output circuit configured to output the repair detection signal as the repair result signal when the repair output signal is input.

11. The electronic device of claim 10, wherein the bootup control circuit comprises:
a bootup period control circuit configured to generate a bootup start signal that is enabled when the bootup signal is received by the bootup period control circuit, configured to generate a bootup end signal that is enabled after the first and second bootup operation periods, configured to generate a first bootup flag that is enabled during the first bootup operation period, and configured to generate a second bootup flag that is enabled during the second bootup operation period; and
a bootup counting signal generation circuit configured to generate the bootup counting signal comprising a pulse that is periodically generated from timing at which the bootup start signal is enabled to timing at which the bootup end signal is enabled.

12. The electronic device of claim 10, wherein the repair detection circuit comprises:
an address latch circuit configured to latch the address that is input during the first bootup operation period, configured to generate the first row address from the latched address, configured to latch the address that is input during the second bootup operation period, and configured to generate the second row address from the latched address;
an address comparison circuit configured to generate the comparison signal by comparing the first and second row addresses and the first and second fuse data during a period in which a target period signal is enabled; and
a repair detection signal generation circuit configured to generate the repair detection signal based on the comparison signal during periods in which the first and second bootup flags are enabled.

13. The electronic device of claim 12, wherein the repair detection signal generation circuit comprises:
a first counting circuit configured to receive the comparison signal and the first bootup flag to generate a first counting signal based on the comparison signal during the period in which the first bootup flag is enabled;
a second counting circuit configured to receive the comparison signal and the second bootup flag to generate the second counting signal based on the comparison signal during the period in which the second bootup flag is enabled; and
a repair comparison circuit configured to receive the first and second counting signals to generate the repair detection signal by comparing the first counting signal and the second counting signal.

14. The electronic device of claim 7, wherein:
the fuse circuit is configured to generate the first fuse data by performing the first rupture operation on a plurality of fuses based on a fail address when a rupture signal is enabled prior to the first bootup operation and to output the first fuse data after the start of the first bootup operation, and
the fuse circuit is configured to generate the second fuse data by performing the second rupture operation on the plurality of fuses based on the fail address when the rupture signal is enabled prior to the second bootup operation and to output the second fuse data after the start of the second bootup operation.

15. An electronic device comprising:
a repair control circuit configured to receive a bootup signal to generate a bootup counting signal comprising a pulse that is periodically generated after a start of first and second bootup operations, configured to generate a comparison signal after comparing first and second row addresses that are received by the repair control circuit after the start of the first and second bootup operations and the generation of first and second fuse data, configured to generate a repair result signal for detecting whether first and second rupture operations are additionally performed based on the comparison signal and first and second fuse addresses, and configured to output the repair result signal to an outside of the electronic device when the repair output signal is received by the repair control circuit; and
a fuse circuit configured to output first and second fuse data, the first and second fuse data generated by the first and second rupture operations and the first and second fuse addresses based on the bootup counting signal.

16. The electronic device of claim 15, wherein:
the first fuse address is a signal comprising information including a location at which the first fuse data have been stored, and
the second fuse address is a signal comprising information including a location at which the second fuse data have been stored.

17. The electronic device of claim 15, wherein the comparison signal is a signal that is enabled when the first row address and the first fuse data have an identical logic level combination after the start of the first bootup operation and that is enabled when the second row address and the second fuse data have an identical logic level combination after the start of the second bootup operation.

18. The electronic device of claim 15, wherein the repair control circuit comprises:
a bootup control circuit configured to generate the bootup counting signal comprising a pulse that is periodically generated when the bootup signal is received by the bootup control circuit, configured to generate a first bootup flag that is enabled during a first bootup operation period in response to receiving the bootup signal, and configured to generate a second bootup flag that is enabled during a second bootup operation period in response to receiving the bootup signal;
a repair detection circuit configured to generate the comparison signal by comparing an address and the first and second fuse data during a period in which the first bootup flag and the second bootup flag are enabled and configured to generate a repair detection signal by latching the first and second fuse addresses when the comparison signal is enabled; and
a repair result signal output circuit configured to output the repair detection signal as the repair result signal when the repair output signal is input.

19. The electronic device of claim 18, wherein the bootup control circuit comprises:
a bootup period control circuit configured to generate a bootup start signal that is enabled when the bootup signal is received by the bootup period control circuit, configured to generate a bootup end signal that is enabled after the first and second bootup operation periods, configured to generate a first bootup flag that is enabled during the first bootup operation period, and configured to generate a second bootup flag that is enabled during the second bootup operation period; and
a bootup counting signal generation circuit configured to generate the bootup counting signal comprising a pulse that is periodically generated from timing at which the bootup start signal is enabled to timing at which the bootup end signal is enabled.

20. The electronic device of claim 18, wherein the repair detection circuit comprises:
an address latch circuit configured to latch the address that is input during the first bootup operation period, configured to generate the first row address from the latched address, configured to latch the address that is input during the second bootup operation period, and configured to generate the second row address from the latched address;
an address comparison circuit configured to generate the comparison signal by comparing the first and second row addresses and the first and second fuse data during a period in which a target period signal is enabled; and
a repair detection signal generation circuit configured to latch the first and second fuse addresses when the comparison signal is enabled during the periods in which the first and second bootup flags are enabled, and configured to generate the repair detection signal by comparing the first and second fuse addresses that have been latched.

21. The electronic device of claim 20, wherein the repair detection signal generation circuit comprises:
a first fuse address latch circuit configured to receive the comparison signal, first bootup flag, and first fuse address to latch the first fuse address when the comparison signal is enabled during the period in which the first bootup flag is enabled and configured to output the first fuse address that has been latched as the first latch address;
a second fuse address latch circuit configured to receive the comparison signal, second bootup flag, and second fuse address to latch the second fuse address when the comparison signal is enabled during the period in which the second bootup flag is enabled and configured to output the second fuse address that has been latched as the second latch address; and
a repair comparison circuit configured to receive the first and second latch addresses to generate the repair detection signal by comparing the first latch address and the second latch address.

22. The electronic device of claim 15, wherein:
the fuse circuit is configured to generate the first fuse data by performing the first rupture operation on a plurality of fuses based on a fail address when a rupture signal is enabled prior to the first bootup operation and to output the first fuse data and the first fuse address after the start of the first bootup operation, and
the fuse circuit is configured to generate the second fuse data by performing the second rupture operation on the plurality of fuses based on the fail address when the rupture signal is enabled prior to the second bootup operation and to output the second fuse data and the second fuse address after the start of the second bootup operation.
